(19) United States
(12) Patent Application Publication
(10) Pub. No.: US 2007/0168775 A1
(43) Pub. Date: Jul. 19, 2007

(54) Programmable Memory Test Controller

(75) Inventors: Mukul TIKOTKAR, Bangalore (IN); Anand BHAT, Bangalore (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/161,437

(22) Filed: Aug. 3, 2005

(51) Int. Cl. G11C 29/00

(52) U.S. Cl. 714/718

(57) ABSTRACT

Providing a programmable test controller integrated along with a random access memory (RAM). The programmable test controller can be programmed to test desired memory locations. Due to such a feature, the same design of the test controller can be integrated into several implementations (varying by design, fabrication parameters, design rules, etc.).

### BACKGROUND

1. Field of the Invention

The present invention relates generally to testing of random access memories, and more specifically to a method and apparatus which provides a flexible approach to test a memory unit using built in self test (BIST) approach.

2. Related Art

Random access memories (RAM) are often tested using built in self test (BIST) approaches. In a typical scenario, a test circuitry is embedded along with a RAM in a memory unit. The test circuitry generates various read and write commands to verify that the RAM is operating as desired. In general, the read and write operations are performed on a subset of the memory locations only, for example, to minimize test time.

In one prior embodiment, a test circuitry is designed to test the operation of an associated RAM at locations determined by a pre-specified approach (“algorithm”). That is, the same approach would control the specific memory locations that would be tested by the test circuitry.

One problem with such embodiments is that a user may not have much control over the specific memory locations tested. Such enhanced control for a user may be desirable in several environments.

For example, a large enterprise may design RAMs of different sizes using different technologies (fabrication processes of 90 nanometer, 65 nanometer, etc.), and it may be desirable to incorporate the same design of the test circuitry into all the corresponding memory units, for example, to reduce duplication of design effort.

In such a scenario, it may be desirable to provide a user more control over the specific locations that would be tested for each unit of the RAM. As an illustration, different technologies present different problems, and the user may need more control to test desired memory locations, as suited for the specific combination of size/technology.

Accordingly what is needed is a test circuit design which provides more flexibility in selecting memory locations in testing different RAMs.

### BRIEF DESCRIPTION OF THE DRAWINGS

The present invention will be described with reference to the following accompanying

drawings.

Figure (FIG.) 1 is a block diagram illustrating a test environment in which various aspects of the present invention can be implemented.

FIG. 2 is a block diagram illustrating the details of implementation of a programmable memory test controller in an embodiment of the present invention.

FIG. 3 is a block diagram illustrating the details of registers contained in a programmable memory test controller in an embodiment of the present invention.

FIG. 4 is a set of instructions in a test algorithm which perform various operations in the testing of a RAM.

In the drawings, like reference numbers generally indicate identical, functionally similar, and/or structurally similar elements. The drawing in which an element first appears is indicated by the leftmost digit (s) in the corresponding reference number.

### DETAILED DESCRIPTION

### 1. Overview

An aspect of the present invention provides a programmable test controller which can be configured to select different memory locations for testing in different configurations. In one embodiment, the test controller contains multiple registers which can be set by a programmer to desired values during operation, and the registers control the specific memory locations which are tested. Accordingly, a control unit is also provided, which receives commands indicating the specific register into which a provided parameter value is written, and the written values then control the specific memory locations tested.

The programmability of the test controllers may lead to several benefits. For example, an enterprise may use the same design of the testing circuitry associated with different versions of memory unit design, since a programmer can later decide the specific memory locations to be tested depending on the implementation and other requirements.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well known structures or operations are not shown in detail to avoid obscuring the features of the invention.

### 2. Example Environment

FIG. 1 is a block diagram illustrating the details of an example environment in which various aspects of the present invention can be implemented. The environment is shown containing tester 110 used to test memory unit 160. Memory unit 160 in turn is shown containing programmable test controller 150 and random access memory (RAM) 170. Each block is described in further detail below.

RAM 170 contains memory locations, which can be written into and read from. Each memory location is specified by a corresponding address. The control (e.g., indicating whether it is a read access or a write access, the access address, etc.) and data (e.g., value to be written and value retrieved) may be contained in path 157.

Programmable test controller 150 provides the data and control signals corresponding to each test on path 157. At least some of the data and control signals are controlled by the specific control signals/values received from tester 110 according to various aspects of the present invention. Accordingly, a user/designer may control the operation of tester 110 to test any desired memory locations, which can be different for different memory units (whether of same design or different design).

The operation and implementation of tester 110 generally depends on the implementation of programmable test controller 150. Accordingly, the description is continued with respect to an example implementation of programmable test controller 150 assuming that the following data/signals are exchanged between RAM 170 and programmable test controller 150.

req: A valid request is defined by the other interface signals in the present test cycle

rnw (read/write): Indicates whether the present operation is a read operation (logic low) or a write operation (logic high)

addr: The access address for the present test cycle

wdata: The data to be written at the access address if rnw indicates a write operation

rdata: The data received from the location at addr in response to a read operation

### 3. Programmable Test Controller

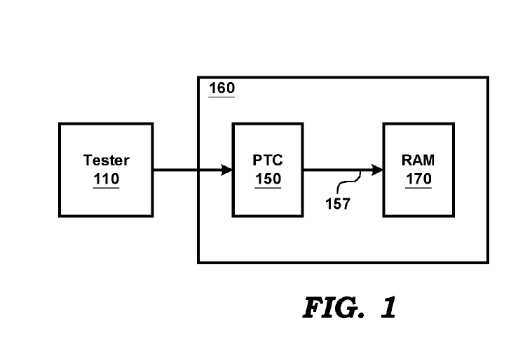

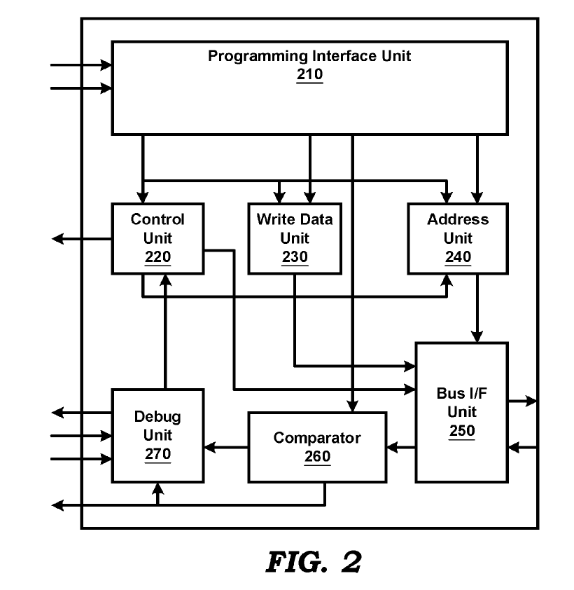

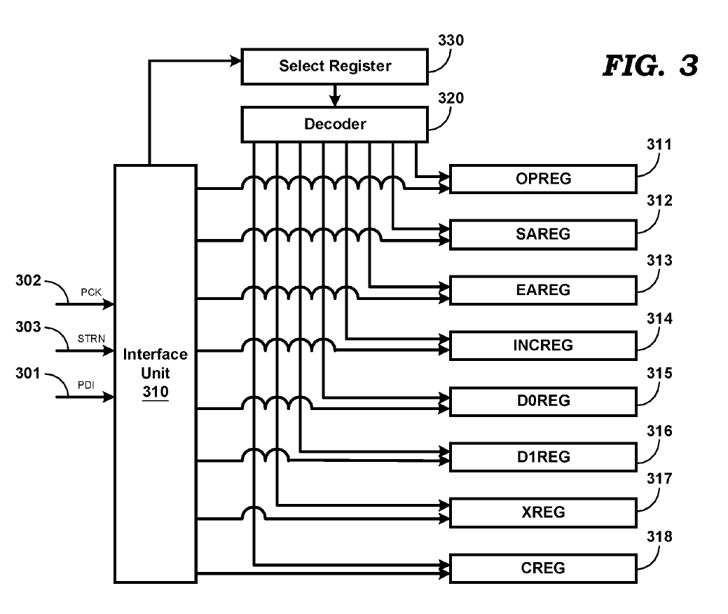

FIG. 2 is a block diagram illustrating the details of programmable test controller 150 in one embodiment. Programmable test controller 150 is shown containing programming interface unit 210, control unit 220, write data unit 230, address unit 240, bus interface unit 250, and comparator 260 and debug unit 270. Each block is described below in further detail.

Control unit 220 generates req and rnw signals with appropriate logic levels depending on an opcode. As will be appreciated from the description below, a single opcode may specify read or write operations for multiple successive test cycles, and control unit 220 generates the req and rnw signals accordingly. To generate the signals for multiple test cycles based on a single opcode, a state machine may be maintained internally.

Write data unit 230 generates the present value to be written in a test cycle. One of two write values received from programming interface unit 210 may be used as the present value, depending on a specific control bit also received from programming interface unit 210.

Address unit 240 generates a present access address for each test cycle based on various values received from programming interface unit 210 and control unit 220. In one embodiment, the received values equals a start address, an end address and an increment value. For illustrating, assuming that values of 0, 8 and 2 are respectively received for start address, end address and increment value, address unit 240 generates addresses of 0, 2, 4, 6 and 8 in successive test cycles. The start of each test cycle may be determined by a clock (not shown).

Bus interface unit 250 generates the appropriate signals (on path 251) consistent with the interface requirements of RAM 170 based on various inputs received from control unit 220, address unit 240, and write data unit 230 (in case of write operation). The data retrieved (on path 252) in response to read operation is forwarded to comparator 260.

Comparator 260 compares the data received from bus interface unit 250 with the expected data (received from programming interface unit 210). In an embodiment, the expected data is present in one of two registers contained in programming interface unit 210, and the specific register is specified by a bit in the received opcode. The result of the comparison is provided on pass/fail path 261 to tester 110.

Debug unit 270 logs the various data units of interest when a fail result is indicated on pass/fail path 261. The logged data may be provided using a serial interface to tester 110, and a hold signal may be generated to control unit 220 to prevent additional read and write commands from being issued while the debug information is being transferred to tester 110.

Programming interface unit 210 contains various registers (which provide various values described above to other units), which can be written into (or programmed) using a convenient interface. Such writing enables any desired memory locations to be tested. The description is continued with respect to the various registers in one embodiment.

### 4. Registers in Programming Interface Unit

In one embodiment, the programmability of test controller 150 is attained by including several registers, which can be set to specific values to cause specific memory locations in RAM 170 to be tested. The internals of test controller 150 in one embodiment are described below in further detail.

1. OPREG (RO) (Opcode Register) 311: This is a 6_bit register, in which the 4_bit LSB field specifies an Opcode for control unit 220. Bit 5 and bit 6 are respectively referred to as W0 and W1 in the description below. If only one register is applicable to the operation specified by the opcode, w0 specifies whether the operation should use the data pattern 0 or 1 (D0REG or D1REG identified as data-0 and data-1 patterns respectively, and described below). For example, when bit 5 is set to a value of 0, the operation uses a data 0-pattern to write into the memory and when the bit is set to a value of 1, opcode uses a data-1 pattern to write into the memory. If two registers are applicable to the operation, bit 6 similarly specifies the second register.

2. SAREG (RI) (Starting Address Register) 312: This register is used to specify a starting address for exercising memory tests. The width of this register is the same as the address bus_width of the system memories.

3. EAREG (R2) (Ending Address Register) 313: This register is used for specifying the ending address for exercising memory tests. The width of this register is the same as the address bus_width of the system memories.

4. INCRREG (R3) (Increment Register) 314: This register is used for specifying the address increment for exercising memory tests. The width of this register is 2_bits.

5. D0REG (R4) (Data_{—}0 Register) 315: This register specifies the data_{—}0 reference pattern that can be used for writing onto the memory locations. It can also be used as a compare data pattern during read_compare operation. This eliminates the need to have a separate compare data register. The width of this register is the same as the data bus_width of system memories.

6. D1REG (R5) (Data_{—}1 Register) 316: This register specifies the data_{—}1 reference pattern that can be used for writing onto the memory locations. It can also be used as a compare data pattern during read_compare operation. The width of this register is the same as the data bus_width of system memories.

7. XREG (R6) (Compare Register Indicator) 317: This is a 2_bit register, with each bit being identified by X0 and X1 in the description henceforth. Each bit specifies whether the compare data needs to be data_{—}0 pattern (315) or data_{—}1 pattern (316). Here, advantage has been taken of the fact that in most memory tests, the write data used in the previous write operation is the same as the compare data in the following read_compare operation. However, alternative embodiments can use different register units as compare registers and data registers.

8. CREG (R7) (Control Register) 318: This register specifies the start of a memory test operation. This is a 1_bit register that gets set after all the other programming registers are initialized. The output of this register indicates, to the hardware state_machines, that the programming data is valid. Once the test completes, this register is automatically reset.

9. SELREG (R8) (Select Register) 330: Select register is a 3_bit register that allows selective programming of above noted configuration registers. During each programming sequence, the select register gets programmed first. The contents of this register point to the register that would be programmed next. Once the selected register gets programmed, the same sequence is repeated for programming other registers. After all the registers are programmed, the control register (CREG) is selected and initialized to a ‘1’. This kicks off the memory test controller state_machines.

Thus, in the corresponding embodiment, path 115 contains only three signals—PDI 301 (data bits in sequential order), PCK 302 (providing a clock reference for the data on PDI), and PRSTN 303 (to reset registers CREG, SELREG, etc.). Thus, after PRSTN 303 is asserted, interface unit 310 writes the first 3-bits (received on PDI 301) into select register 330.

Decoder 320 decodes the value in select register 330 and asserts only one of lines 331-338 to cause only the corresponding one of registers 311-318 to store (by shift operation) the following bits received on PDI 301. The number of bits caused to be stored equals the width of the corresponding register.

CREG 318 is programmed last (to set to 1) to cause the operation corresponding to the opcode stored in OPREG to be executed. Accordingly, control unit 220 needs to examine the status of write operations to CREG 318, and then start execution of instructions corresponding to the opcode in OPREG 311 once all bits in CREG 318 are set to 1. The opcodes need to be designed to facilitate selection of various memory locations, and subsequent testing of the selected locations. The various opcodes in an example embodiment are described below.

### 5. Opcodes

In an embodiment, the opcodes saved in OPREG 311 correspond to the following instructions described briefly below. The corresponding mnemonic and the sequence of read/write operations performed are conveniently noted in the parenthesis:

1. Single Write (sinWrite, W0): Single Write performs (or is designed to perform) a single write operation to each of the locations (in RAM 170) determined by SAREG 312, EAREG 313, and INCREG 314. In general, the first address is determined to equal the start address (in SARG 312), and the address is incremented by the value in INCREG 314 until the end address (in EAREG 313) is reached. The 5^{th} bit of the data (W0) stored in OPREG 311 indicates the specific register (315 or 316) which provides the data for the write operations.

2. Single Read (sinRead, X0): Single Read performs single read operations from a single location determined by SAREG 312, EAREG 313, and INCREG 314, and increment register 314 (as described above). X0 (first bit of XREG 317) specifies whether the retrieved data is to be compared with D0REG 315 or D1REG 316. During each read, the retrieved data is compared to an expected data value using X0 field of XREG 317.

3. Double Write (dblWrite (W0,1)): In comparison to Single Write, Double Write causes data in D0REG 315 and D1REG 316 to be respectively written into two consecutive locations starting from each memory address determined by SAREG 312, EAREG 313, and INCREG 314.

4. Double Read (dblRead, X0,1) _ In comparison to Single Read, Double Read performs two sequential memory reads (on consecutive memory locations) and corresponding data comparisons. The access address is incremented between the two sequential reads within the same sequence. The specific data (D0REG 315 or D1REG 316) to be compared with is respectively specified by the two bits of XREG.

5. Read0_Write1_Write 1 (rwwSeq, X0, W0,1 Sequence): This sequence performs read operation from each location (as indicated by the combination of SAREG 312, EAREG 313, and INCREG 314), compares the retrieved data with D0REG 315 or D1REG 316 as specified by X0, and writes the data provided by the register (D0REG 315 or D1REG 316) specified by W0 in the present location and the data provided by the register specified by W1 in the following location.

6. (Read0_Write0_Read1 Sequence) rwrSeq, X0, W0, x1: This sequence performs read operation from each memory location (as indicated by the combination of SAREG 312, EAREG 313, and INCREG 314), compares retrieved data from the present location with data in either D0REG 315 or D1REG 316 as specified by X0, writes data from D0REG 315 or D1REG 316 as specified by W0 in the presently accessed address location, reads data from the next memory location (determined by incrementing the value in INCREG 314), and compares with data in either D0REG 315 or D1REG 316 as specified by X1.

7. (Reverse Read0_Write0_Write 1 Sequence) uprwwSeq, X0, W0,1: Here, the memory location addresses are determined in the reverse order starting from the address specified in EAREG 313, until the address location specified in SAREG 312 is reached while decrementing addresses by INCREG 314. The sequence of operations on each memory location include (reading of the data at the memory location and comparison with the register specified by X0), and write the data specified by W0 (5^{th} bit in OPREG 311) in the memory location, and write data specified by W1 (6^{th} bit in OPREG 311) in the previous location.

8. (Read0_Write0_Read1 Sequence) uprwrSeq, X0, W0, X1: Here also the memory location addresses are determined in the reverse order as above. In comparison to the uprwwSeq, a read operation from the previous location (and comparison with data in the register specified by X1) is performed last (instead of a write operation).

9. Reverse Read (upRead, X0): This sequence operates similar to SinRead described above, except that the addresses of locations are computed by subtracting the value in INCREG 314.

10. Up_Down Read (updRead, X0,1): This sequence performs read operations for several of the locations between addresses specified by SAREG 312 and EAREG 313. Read operations are performed for memory location specified by SAREG 312 and EAREG 313 (and comparisons performed with data specified by X0 and X1 respectively) in two successive read cycles. The value in SAREG 312 is incremented by INCREG 314 and the value in EAREG 313 is decremented by INCREG 314, to determine the next pair of locations from which the read operations are to be performed.

11. Reverse Write (upWrite, W0): This sequence operates similar to SinWrite described above, except that the addresses of locations are computed by subtracting the value in INCREG 314.

12. Read0_Write_{—}0 Sequence (rwSeq, X0, W0): This sequence performs read operation from each memory location (as indicated by the combination of SAREG 312, EAREG 313, and INCREG 314), compares retrieved data from the present location with data in either D0REG 315 or D1REG 316 as specified by X0 and writes data from D0REG 315 or D1REG 316 as specified by W0 in the presently accessed address location.

Using opcodes such as those described above, tester 110 may execute test algorithms as illustrated below with an example.

### 6. Program

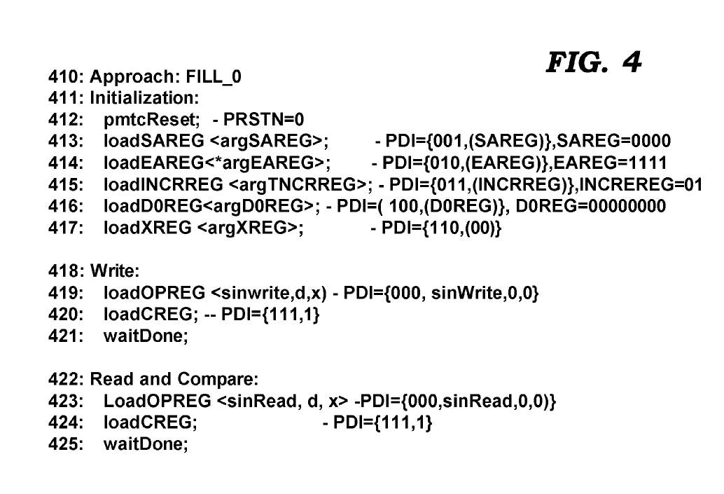

A test algorithm to implement ‘FILL Test’ (well known in the relevant arts) is depicted in FIG. 4. As may be observed, the approach FILL_0 (as in line 410) is shown containing 3 sections—Initialization section (starting at 411), Write Section (starting at 418) and Read and Compare Section (starting at 422), and are described in detail below.

Broadly, the test writes a specific data in each memory location by execution of the corresponding code under Write Section, reading of the data from each of the memory locations and comparing of the read values with the previously written value by execution of the corresponding code under Read And Compare Section. Each of the lines under the three sections is described below in further detail.

The ‘Initialization section’ contains opcodes corresponding to setting of appropriate values in some or all of the registers (R0 to R8). As may be appreciated, the line pmtcReset 412 resets values in all the registers to 0.

Line 413 sets the start address register SAREG 312 to a value of ‘00000’ by passing a parameter value ‘001’ to command loadSAREG. Line 414 sets the end address register EAREG 313 to a value of ‘1111’. Line 415 sets the increment value in INCREG 314 to a value ‘01’. Line 416 sets data-0 register (D0REG 315) to a value ‘00000000’ and line 417 sets the compare register XREG 317 to a value X0. Values in SAREG 312, EAREG 313 and INCREG 314 together determine memory locations to test by performing various operations.

With respect to the write section starting at line 418, in line 419, the value in operation register (OPREG 311) is set to opcode sinWrite indicating a single write operation. The test controller begins write operation in a present access address starting at address location ‘0000’ (value in SAREG 312), when the value in register CREG 318 (line 420) is set to 1. Line 421 indicates that Write operation is performed for all memory address locations until the present access address location equals the value corresponding to a value in EAREG 313.

With respect to the read and compare operations starting at line 422, in line 423, OPREG 311 is set to a value of sinRead indicating that a Single Read operation is to be performed. (SinREAD). As may be appreciated, address locations in SAREG 312, EAREG 313, and INCREG 314 are used to indicate that the READ operation is performed for the same memory locations in which the WRITE was performed earlier (in lines 418-421). As may be appreciated, line 424 begins the read operation by setting the value in register CREG 318 to 1 (similar to in line 420).

Data read from each present access address is compared with the first register value of XREG 317 (line 423), X0. The result of the compare is used to determine whether a present access address is faulty. For example, if the value written into a present access address is the same as the value read from the present access address, sinRead operation returns a TRUE indicating absence of fault based on the present operation. If not, the present access address may be determined to be faulty.

From the above description, it may be appreciated that the programmability of test controller 150 enables desired tests to be designed (as appropriate for the specific design of a memory unit or even specific fabricated memory unit from a common design). As a result, the approach can be used across different designs, while leaving to a tester the specific tests to be performed.

### 7. Conclusion

While various embodiments of the present invention have been described above, it should be understood that they have been presented by way of example only, and not limitation. Thus, the breadth and scope of the present invention should not be limited by any of the above described exemplary embodiments, but should be defined only in accordance with the following claims and their equivalents.

What is claimed is:

1. A memory unit comprising:
a random access memory (RAM) containing a plurality of locations; and
a test controller comprising a first plurality of registers, wherein each of said plurality of registers is designed to be programmed to a corresponding one of a plurality of desired values, wherein the values in said plurality of registers determine the specific ones of said plurality of locations which are accessed for testing,
whereby different locations of said RAM can be tested for different memory units by programming said first plurality of registers.

2. The memory unit of claim 1, wherein said plurality of registers comprise a start address register, an end address register and an increment register, wherein said start address specifies a first address for accessing said RAM, said end address specifies a last address for accessing said RAM, and said increment register specifying a value by which the address is to be incremented or decrement in determining the next address in accessing said RAM.

3. The memory unit of claim 1, further comprising an opcode register programmable to specify a set of operations to be performed to test said RAM.

4. The memory unit of claim 3, wherein said test controller comprises a data register which can be programmed with a desired value, wherein said opcode register is programmable to perform a write operation, and the value in said data register is written into locations specified by said first plurality of registers.

5. The memory unit of claim 4, wherein said test controller comprises a compare register which can be programmed to an expected value, wherein said opcode register is programmable to perform a read operation, and said expected value is automatically compared with a value retrieved by said read operation.

6. The memory unit of claim 5, wherein said compare register and said data register are implemented as a single register.

7. The memory unit of claim 5, wherein said test controller comprises a plurality of compare registers including said compare register, said test controller further comprising a compare register indicator which indicates the specific one of said plurality of compare registers to be used in comparing with said retrieved value.

8. The memory unit of claim 5, further comprising:
a control unit to perform a plurality of access operations in response to an opcode in said opcode register;
an address unit to compute an access address corresponding to each of said plurality of access operations according to said first plurality of registers; and
a bus interface unit coupled to said RAM, wherein each of said access operations are performed through said bus interface unit.

9. The memory unit of claim 8, wherein said plurality of access operations correspond to a Single Write operation in which the desired value in said data register is stored in memory locations specified by said first plurality of registers.

10. The memory unit of claim 8, wherein said plurality of access operations correspond to a Single Read operation in which values are retrieved from memory locations specified by said first plurality of registers, said test controller further comprising a comparator comparing each retrieved value with said expected value in said compare register and providing a result of said comparison.

11. The memory unit of claim 8, wherein said plurality of access operations correspond to a Double Write operation in which data is written into two consecutive locations starting from each location determined by said first plurality of registers.

12. The memory unit of claim 8, wherein said plurality of access operations correspond to a Double Read operation in which data is retrieved from two consecutive locations starting from each location determined by said first plurality of registers.

13. The memory unit of claim 8, wherein said plurality of access operations comprise both a read operation and a write operation.

14. The memory unit of claim 8, further comprising an interface unit receiving data indicating a plurality of data values according to a convention, wherein said convention specifies the specific one of said first plurality of registers, said data register and said compare register in which each of said plurality of data values is to be stored.

15. The memory unit of claim 14, wherein said convention comprises receiving a register identifier associated with each of said plurality of data values, said memory unit further comprising:
a select register to store said register identifier; and
a decoder receiving said register identifier from said select register and enabling storing a corresponding data value in only the register identified by said register identifier.

16. The memory unit of claim 15, wherein said plurality of data values and said register identifiers on a serial communication channel.

17. The memory unit of claim 8, wherein said test controller and said RAM are fabricated into a single integrated circuit.
